(19) United States
(12) Patent Application Publication
(10) Pub. No.: US 2026/0013304 A1
(43) Pub. Date: Jan. 8, 2026

(54) WAVELENGTH CONVERSION DEVICE AND MANUFACTURING METHOD THEREOF

(71) Applicant: Lextar Electronics Corporation, Hsinchu City (TW)

(72) Inventors: Fu-Hsin CHEN, Hsinchu City (TW); Kang-Hung LIU, Hsinchu City (TW); Yu-Chun LEE, Hsinchu City (TW)

(21) Appl. No.: 19/256,972

(22) Filed: Jul. 1, 2025

(30) Foreign Application Priority Data
Jul. 2, 2024 (TW) 113124651

(51) Int. Cl. H10H 29/851; H10H 29/01; H10H 29/855

(52) U.S. Cl. CPC H10H 29/8514; H10H 29/012; H10H 29/0361; H10H 29/0363; H10H 29/8552

(57) ABSTRACT

A wavelength conversion device and a manufacturing method thereof are provided. The wavelength conversion device includes a wavelength conversion module including a carrier, a first light-blocking layer, a second light-blocking layer, a filter layer, a wavelength conversion layer, and a protective layer. The carrier has a first surface and a second surface opposite the first surface. The first light-blocking layer is disposed on the first surface and has a first opening. The second light-blocking layer is disposed on the second surface and has a second opening. The filter layer is disposed on the second surface and in the second opening. The wavelength conversion layer is disposed on the filter layer. The protective layer is disposed on the second light-blocking layer. The width of the second opening of the second light-blocking layer is greater than the width of the first opening of the first light-blocking layer.

### CROSS REFERENCE TO RELATED APPLICATIONS

This application claims priority of Taiwan Patent Application No. TW 113124651, filed on Jul. 2, 2024, the entirety of which is incorporated by reference herein.

### TECHNICAL FIELD

Some embodiments of the present disclosure relate to a wavelength conversion device and a manufacturing method thereof, and, in particular, they relate to a wavelength conversion device that includes a first light-blocking layer and a second light-blocking layer and a manufacturing method of the wavelength conversion device.

### BACKGROUND

A conventional fine pitch package includes a substrate and a light-emitting unit such as a light-emitting diode (LED), wherein the substrate and the light-emitting unit each have a certain thickness or size. Therefore, the size of the package is limited by the substrate and the light-emitting unit, and it leads to limitations in terms of cost and display pitch. In addition, in order to increase contrast or prevent light cross-talk, a photoresist material such as a black matrix may be provided. However, the black matrix may over-absorb light, thereby significantly reducing the light-emitting efficiency of the package.

### SUMMARY

In some embodiments, a wavelength conversion device is provided. The wavelength conversion device includes a wavelength conversion module and a light-emitting module. The wavelength conversion module includes a carrier, a first light-blocking layer, a second light-blocking layer, a filter layer, a wavelength conversion layer, and a protective layer. The carrier has a first surface and a second surface opposite the first surface. The first light-blocking layer is disposed on the first surface and has a first opening. The second light-blocking layer is disposed on the second surface and has a second opening. The filter layer is disposed on the second surface and is disposed in the second opening. The wavelength conversion layer is disposed on the filter layer. The protective layer is disposed on the second light-blocking layer. The light-emitting module is disposed on the wavelength conversion module. The width of the second opening of the second light-blocking layer is greater than the width of the first opening of the first light-blocking layer.

In some embodiments, a method for manufacturing a wavelength conversion device is provided. The manufacturing method includes providing a carrier having a first surface and a second surface opposite the first surface. The manufacturing method includes forming a first light-blocking layer on the first surface, wherein the first light-blocking layer has a first opening. The manufacturing method includes forming a second light-blocking layer on the second surface, wherein the second light-blocking layer has a second opening. The manufacturing method includes forming a filter layer on the second surface and in the second opening. The manufacturing method includes forming a wavelength conversion layer on the filter layer. The manufacturing method includes forming a protective layer on the second light-blocking layer. The manufacturing method includes providing a light-emitting module on the wavelength conversion layer. The width of the second opening of the second light-blocking layer is greater than the width of the first opening of the first light-blocking layer.

The wavelength conversion device and the manufacturing method thereof of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

FIG. 1 is a schematic cross-sectional view of a wavelength conversion device at a stage in a manufacturing method according to some embodiments of the present disclosure.

FIG. 2 is a schematic cross-sectional view of a wavelength conversion device at a stage in a manufacturing method according to some embodiments of the present disclosure.

FIG. 3 is a schematic cross-sectional view of a wavelength conversion device at a stage in a manufacturing method according to some embodiments of the present disclosure.

FIG. 4 is a schematic cross-sectional view of a wavelength conversion device at a stage in a manufacturing method according to some embodiments of the present disclosure.

FIG. 5 is a schematic cross-sectional view of a wavelength conversion device at a stage in a manufacturing method according to some embodiments of the present disclosure.

FIG. 6 is a schematic cross-sectional view of a wavelength conversion device at a stage in a manufacturing method according to some embodiments of the present disclosure.

FIG. 7 is a schematic cross-sectional view of a wavelength conversion device at a stage in a manufacturing method according to some embodiments of the present disclosure.

FIG. 8 is a schematic cross-sectional view of a wavelength conversion device at a stage in a manufacturing method according to some embodiments of the present disclosure.

FIG. 9 is a schematic cross-sectional view of a wavelength conversion device at a stage in a manufacturing method according to some embodiments of the present disclosure.

FIG. 10 is a schematic cross-sectional view of a wavelength conversion device at a stage in a manufacturing method according to some embodiments of the present disclosure.

FIG. 11 is a schematic cross-sectional view of a wavelength conversion device at a stage in a manufacturing method according to some embodiments of the present disclosure.

FIG. 12 is a schematic cross-sectional view of a wavelength conversion device at a stage in a manufacturing method according to some embodiments of the present disclosure.

FIG. 13 is a schematic cross-sectional view of a wavelength conversion device at a stage in a manufacturing method according to some embodiments of the present disclosure.

FIG. 14 is a schematic cross-sectional view showing a wavelength conversion device according to some embodiments of the present disclosure.

### DETAILED DESCRIPTION

The following is a detailed description of the wavelength conversion device and the manufacturing method thereof in various embodiments of the present disclosure.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The term “in a range of a first value to a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

In the present disclosure, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the X-axis is a first direction D1 (the width direction) and the Z-axis is a second direction D2 (the thickness/height direction). In some embodiments, the schematic cross-sectional views of the present disclosure are schematic cross-sectional views observing the XZ plane.

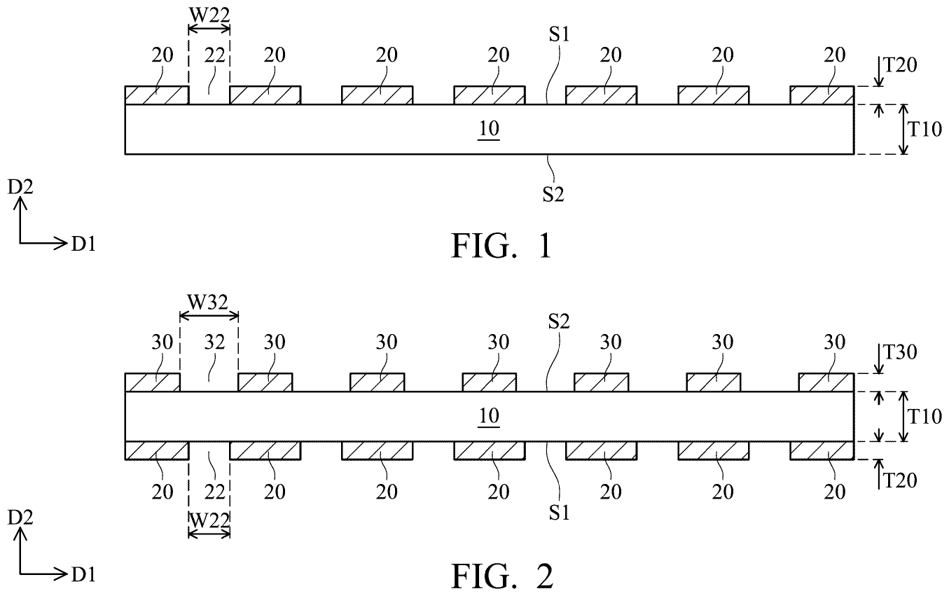

Referring to FIG. 1, it is a schematic cross-sectional view of a wavelength conversion device 1 at a stage in a manufacturing method according to some embodiments of the present disclosure. In some embodiments, as shown in FIG. 1, a carrier 10 may be provided. In some embodiments, the carrier 10 has a first surface S1 and a second surface S2 opposite the first surface S1. In some embodiments, the carrier 0 may include a silicon, a glass, a sapphire, a ceramic, a polyimide (PI), a polycarbonate (PC), a polyethylene terephthalate (PET), a polypropylene (PP), or a combination thereof, but the present disclosure is not limited thereto. For example, the carrier 10 may be a glass carrier. In some embodiments, in the second direction D2, the carrier 10 has a thickness T10, and the thickness T10 of the carrier 10 may be in a range of 100 μm to 600 μm. For example, the thickness T10 of the carrier 10 may be 100 μm, 150 μm, 200 μm, 250 μm, 300 μm, 350 μm, 400 μm, 450 μm, 500 μm, 550 μm, 600 μm, or a range therebetween, but the present disclosure is not limited thereto.

In some embodiments, as shown in FIG. 1, a first light-blocking layer 20 may be formed on the first surface S1 of the carrier 10, and the first light-blocking layer 20 has a first opening 22. In some embodiments, the first light-blocking layer 20 may be formed on the first surface S1 of the carrier 10 by a deposition process, an etching process, an bonding process, a coating process, other suitable processes, or a combination thereof. In some embodiments, the first light-blocking layer 20 may be formed by a photolithography process. In some embodiments, the first opening 22 may expose a portion of the first surface S1 of the carrier 10. In some embodiments, the first light-blocking layer 20 may include a resin, a photoresist material, other suitable light-blocking materials, or a combination thereof, but the present disclosure is not limited thereto. In some embodiments, the first light-blocking layer 20 may be a black glue, a black photoresist material, or a combination thereof. In some embodiments, the absorption rate (absorptivity) of the first light-blocking layer 20 at the wavelength of visible light (for example, 380 nm˜780 nm) may be greater than 80%. For example, the absorption rate of the first light-blocking layer 20 may be greater than 80%, 90%, 95%, 99%, or any value or any range of values between the aforementioned values, but the present disclosure is not limited thereto. Therefore, in the case where the first light-blocking layer 20 has a high absorption rate, light can be blocked (or be shielded).

In some embodiments, in the second direction D2, the first light-blocking layer 20 may have a thickness T20, and the thickness T20 of the first light-blocking layer 20 may be in a range of 10 μm to 30 μm. For example, the thickness T20 of the first light-blocking layer 20 may be 10 μm, 15 μm, 20 μm, 25 μm, 30 μm, or any value or any range of values between the aforementioned values, but the present disclosure is not limited thereto. When the thickness T20 of the first light-blocking layer 20 is less than 10 μm, a light interference may occur. When the thickness T20 of the first light-blocking layer 20 is greater than 30 μm, the light emitted by the subsequently formed light-emitting element may be over-absorbed, thereby reducing the light-emitting efficiency.

In some embodiments, in the first direction D1, the first opening 22 between adjacent first light-blocking layers 20 may have a width W22, and the width W22 of the first opening 22 may be in a range of 5 μm to 500 μm. For example, the width W22 of the first opening 22 may be 5 μm, 10 μm, 50 μm, 100 μm, 200 μm, 300 μm, 400 μm, 500 μm, or any value or any range of values between the aforementioned values, but the present disclosure is not limited thereto. When the width W22 is smaller, the pixel resolution is higher, and when the width W22 is larger, the pixel resolution is lower. In addition, the width W22 of the first opening 22 may be smaller than the width of the second opening to be formed subsequently (for example, the width W32 of the second opening 32 shown in FIG. 2) to avoid the problem of light interference.

Referring to FIG. 2, it is a schematic cross-sectional view of a wavelength conversion device 1 at a stage in a manufacturing method according to some embodiments of the present disclosure. In some embodiments, the structure shown in FIG. 1 may be flipped upside down. Next, a second light-blocking layer 30 may be formed on the second surface S2 of the carrier 10, and the second light-blocking layer 30 may have a second opening 32. In some embodiments, the material and the formation method of the second light-blocking layer 30 may be the same as or different from the material and the formation method of the first light-blocking layer 20. In some embodiments, the second light-blocking layer 30 may be a black glue, a black photoresist material, or a combination thereof.

In some embodiments, in the first direction D1, the second opening 32 between adjacent second light-blocking layers 30 may have a width W32, and the width W32 of the second opening 32 may be in a range of 10 μm to 600 μm. For example, the width W32 of the second opening 32 may be 10 μm, 50 μm, 100 μm, 200 μm, 300 μm, 400 μm, 500 μm, 600 μm, or any value or any range of values between the aforementioned values, but the present disclosure is not limited thereto. The obtained mixed light can be adjusted by adjusting the width W32 of the second opening 32. In some embodiments, the width W32 of the second opening 32 of the second light-blocking layer 30 may be greater than the width W22 of the first opening 22 of the first light-blocking layer 20. In some embodiments, the projection of the second light-blocking layer 30 on the carrier 10 may be located within the projection of the first light-blocking layer 20 on the carrier 10. Accordingly, it is possible to increase the contrast of the light-emitting surface of the subsequently formed wavelength conversion module and/or prevent light from interfering with each other. In some other embodiments, the second light-blocking layer 30 may be formed on the second surface S2 of the carrier 10, and then the first light-blocking layer 20 may be formed on the first surface S1 of the carrier 10.

In some embodiments, in the second direction D2, the second light-blocking layer 30 may have a thickness T30, and the thickness T30 of the second light-blocking layer 30 may be in a range of 10 μm to 50 μm. For example, the thickness T30 of the second light-blocking layer 30 may be 10 μm, 15 μm, 20 μm, 25 μm, 30 μm, 35 μm, 40 μm, 45 μm, 50 μm, or any value or any range of values between the aforementioned values, but the present disclosure is not limited thereto. When the thickness T30 of the second light-blocking layer 30 is less than 10 μm, a light interference may be occurred. When the thickness T30 of the second light-blocking layer 30 is greater than 50 μm, the light emitted by the light-emitting element may be over-absorbed, thereby reducing the light-emitting efficiency.

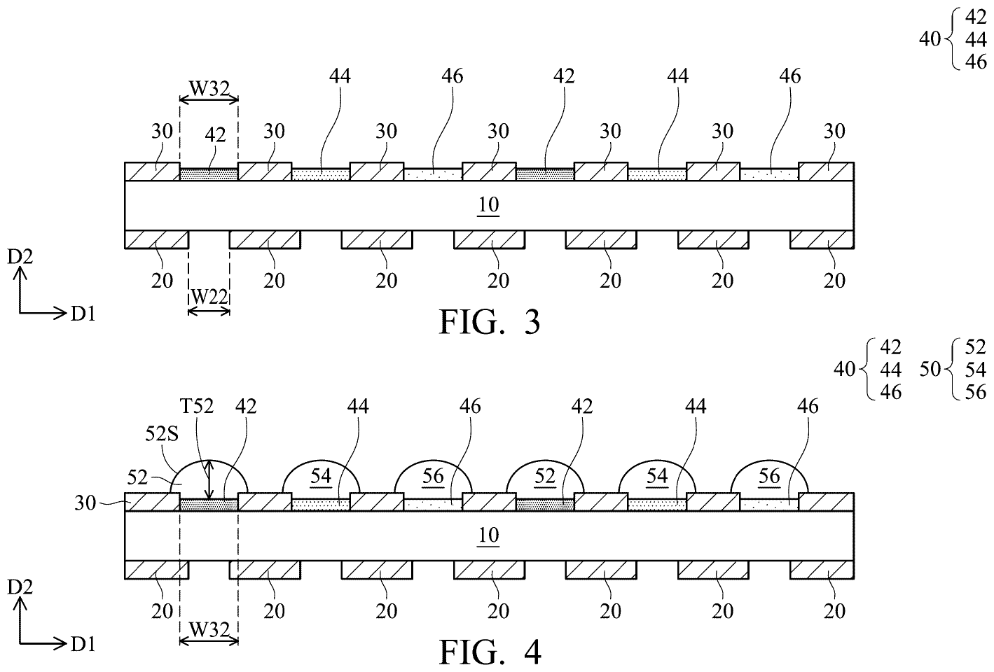

Referring to FIG. 3, it is a schematic cross-sectional view of a wavelength conversion device 1 at a stage in a manufacturing method according to some embodiments of the present disclosure. In some embodiments, as shown in FIG. 3, a filter layer 40 may be formed on the second surface S2 of the carrier 10, and the filter layer 40 may be disposed in the second opening 32. In some embodiments, the filter layer 40 may include a first filter 42, a second filter 44, and a third filter 46 respectively corresponding to different wavelengths. In other words, the first filter 42, the second filter 44, and the third filter 46 can filter light of different wavelengths respectively and allow light of different wavelengths to pass through. In some embodiments, the first filter 42, the second filter 44, and the third filter 46 may be red filters, green filters, and blue filters, respectively.

In some embodiments, the filter layer 40 may be formed in the second opening 32 by coating the material of the filter layer 40 on the second surface S2 of the carrier 10 and in the second opening 32, and then curing the material of the filter layer 40. In some embodiments, since the width W32 of the second opening 32 may be greater than the width W22 of the first opening 22, the width of the filter layer 40 may be greater than the width W22 of the first opening 22. Therefore, the light passing through the second opening 32 and then passing through the first opening 22 may be completed processed (for example, filtered).

Referring to FIG. 4, it is a schematic cross-sectional view of a wavelength conversion device 1 at a stage in a manufacturing method according to some embodiments of the present disclosure. In some embodiments, as shown in FIG. 4, a wavelength conversion layer 50 may be formed on the filter layer 40. In some embodiments, the wavelength conversion layer 50 may be in direct contact with the filter layer 40. In some embodiments, the wavelength conversion layer 50 may include a first wavelength conversion unit 52, a second wavelength conversion unit 54, and a third wavelength conversion unit 56 respectively corresponding to different wavelengths. In some embodiments, the first wavelength conversion unit 52, the second wavelength conversion unit 54, and the third wavelength conversion unit 56 may be disposed at intervals. In other words, there may be a distance between the first wavelength conversion unit 52 and the second wavelength conversion unit 54, and there may be a distance between the second wavelength conversion unit 54 the third wavelength conversion unit 56. Accordingly, the waste of materials of the wavelength conversion layer can be reduced, the process cost can be reduced, and/or the light interference can be prevented. In some embodiments, the wavelength conversion layer 50 may be disposed corresponding to the type of light emitted by the subsequently disposed light-emitting element. In some embodiments, the first wavelength conversion unit 52 may be disposed on the first filter 42, the second wavelength conversion unit 54 may be disposed on the second filter 44, and the third wavelength conversion unit 56 may be disposed on the third filter 46.

In some embodiments, the wavelength conversion layer 50 may be formed by micro-jetting (droplet-jetting) the material of the wavelength conversion layer 50 on the filter layer 40 and in the second opening 32 of the second light-blocking layer 30, and then curing the material of the wavelength conversion layer 50. In some embodiments, the wavelength conversion layer 50 may cover a portion of the top surface of the second light-blocking layer 30 and expose another portion of the top surface of the second light-blocking layer 30. In some embodiments, since the wavelength conversion layer 50 is formed by a micro-jetting process, when viewed in a cross-sectional view, a portion of a side surface of the wavelength conversion layer 50 may be a curved (arc-shaped) side surface. In other words, a portion of the wavelength conversion layer 50 may be accommodated in the concave portion formed by the second light-blocking layer 30 and the filter layer 40.

In some embodiments, when viewed in cross-section, the wavelength conversion layer 50 may have a semicircular shape, semielliptical shape, bullet shape, other similar shapes, or a combination thereof, but the present disclosure is not limited thereto. In some embodiments, the radius curvature of the curved side surface of the wavelength conversion layer 50 may be in a range of 0.03 mm to 0.3 mm. For example, the radius curvature of the curved side surface may be 0.03 mm, 0.05 mm, 0.08 mm, 0.1 mm, 0.2 mm, 0.3 mm, or any value or any range of values between the aforementioned values, but the present disclosure is not limited thereto. For example, the curvature radius of the curved side surface may be adjusted corresponding to the width W32 of the second opening 32. Accordingly, since the side surface of the wavelength conversion layer 50 may be an curved side surface, the side light-emitting efficiency of the light emitted from the light-emitting unit can be increased.

In some embodiments, in the second direction D2, the first wavelength conversion unit 52 may have a thickness T52, and the thickness T52 of the first wavelength conversion unit 52 may be in a range of 10 μm to 100 μm. For example, the thickness T52 of the first wavelength conversion unit 52 may be 10 μm, 10 μm, 30 μm, 40 μm, 50 μm, 60 μm, 70 μm, 80 μm, 90 μm, 100 μm, or any value or any range of values between the aforementioned values, but the present disclosure is not limited thereto. When the thickness T52 of the first wavelength conversion unit 52 is less than 10 μm, the wavelength conversion efficiency may be insufficient, and when the thickness T52 of the first wavelength conversion unit 52 is greater than 100 μm, the light emitted by the light-emitting element may be over-absorbed, thereby reducing the light-emitting efficiency.

In some embodiments, the wavelength conversion layer 50 may include a transparent material as a matrix. In some embodiments, the transparent material may include a transparent resin. For example, the transparent material may be an acrylate resin, an organosilicone resin, an acrylate-modified polyurethane, an acrylate-modified organosilicon resin, an epoxy resin, the like, or a combination thereof, but the present disclosure is not limited thereto. In some embodiments, the wavelength conversion layer 50 may further include a wavelength conversion material dispersed in the transparent material. In some embodiments, the wavelength conversion material may include a red light conversion material, a blue light conversion material, a green light conversion material, a yellow light conversion material, other suitable light conversion materials, or a combination thereof. In some embodiments, the red light conversion material may be a red quantum dot material or a red phosphor, but the present disclosure is not limited thereto. For example, the red light conversion material may be (Sr, Ca) AlSiN3: Eu2+, Ca2Si5N8: Eu2+, Sr(LiAl3N4): Eu2+, K2GeF6: Mn4+, K2SiF6: Mn4+, K2TiF6: Mn4+, the like, or a combination thereof, but the present disclosure is not limited thereto. In some embodiments, the blue light conversion material may be a blue quantum dot material or a blue phosphor, but the present disclosure is not limited thereto. In some embodiments, the green light conversion material may be a green quantum dot material or a green phosphor, but the present disclosure is not limited thereto. For example, the green light conversion material may be LuAG phosphor, YAG phosphor, β-SiAlON phosphor, silicate phosphor, the like, or a combination thereof, but the present disclosure is not limited thereto. In some embodiments, the yellow light conversion material may be a yellow quantum dot material or a yellow phosphor. For example, the yellow light conversion material may be yttrium aluminum garnet (YAG) phosphor.

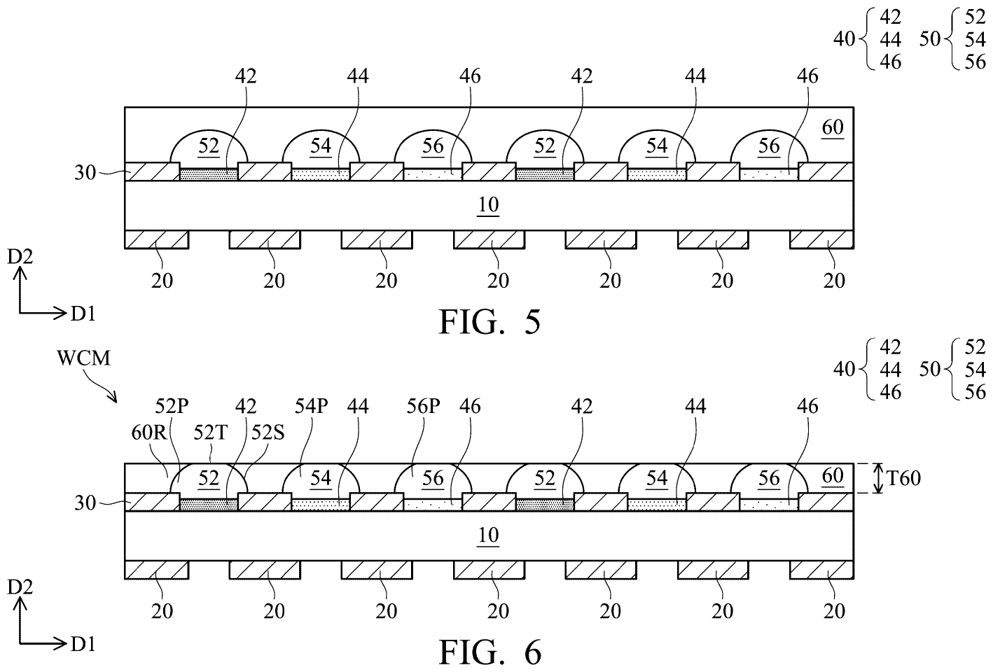

Referring to FIG. 5, it is a schematic cross-sectional view of a wavelength conversion device 1 at a stage in a manufacturing method according to some embodiments of the present disclosure. In some embodiments, as shown in FIG. 5, a protective layer 60 may be formed on the second light-blocking layer 30 and the wavelength conversion layer 50. In some embodiments, the protective layer 60 may include a reflective material. In some embodiments, the reflective material may include a white reflective material (such as, a white paint or other white material), a white photoresist material, the like, or a combination thereof, but the present disclosure is not limited thereto. In some embodiments, the reflectivity of the reflective material of the protective layer 60 at the wavelength of visible light may be greater than or equal to 80%. For example, the reflectivity of the reflective material at the wavelength of visible light may be greater than 80%, 90%, 95%, 99%, or any value or any range of values between the aforementioned values, but the present disclosure is not limited thereto. In some embodiments, the side surface of the wavelength conversion layer 50 may be in direct contact with the protective layer 60, so the protective layer 60 can protect the wavelength conversion layer 50 and the elements thereunder, and the protective layer 60 can improve the light-emitting efficiency.

Referring to FIG. 6, it is a schematic cross-sectional view of a wavelength conversion device 1 at a stage in a manufacturing method according to some embodiments of the present disclosure. In some embodiments, as shown in FIG. 6, a planarization process may be performed to remove a portion of the protective layer 60 and a portion of the wavelength conversion layer 50, so that the top surface of the protective layer 60 may be substantially coplanar (or flush) with the top surface of the wavelength conversion layer 50. Therefore, a wavelength conversion module WCM can be obtained. In some embodiments, the planarization process may include a chemical mechanical polishing (CMP) process. In some embodiments, since a portion of the wavelength conversion layer 50 has been removed, the top surface of the wavelength conversion layer 50 may be a flat surface. In some embodiments, the protective layer 60 may expose the top surface of the wavelength conversion layer 50. In some embodiments, in the second direction D2, the protective layer 60 may have a thickness T60, and the thickness T60 of the protective layer 60 may be in a range of 10 μm to 100 μm. For example, the thickness T60 of the protective layer 60 may be 10 μm, 10 μm, 30 μm, 40 μm, 50 μm, 60 μm, 70 μm, 80 μm, 90 μm, 100 μm, or any value or any range of values between the aforementioned values, but the present disclosure is not limited thereto.

In some embodiments, a portion of the side surface 52S of the first wavelength conversion unit 52 of the wavelength conversion layer 50 may be a curved side surface. Similarly, the second wavelength conversion unit 54 and the third wavelength conversion unit 56 of the wavelength conversion layer 50 may also have curved side surfaces. In some embodiments, the first wavelength conversion unit 52 of the wavelength conversion layer 50 may have a convex portion 52P, the protective layer 60 may have concave portions 60R, and one of the concave portions 60R of the protective layer 60 corresponds to the convex portion 52P. Similarly, the second wavelength conversion unit 54 and the third wavelength conversion unit 56 of the wavelength conversion layer 50 may also have a convex portion 54P and a convex portion 56P respectively, and the convex portions 52P, 54P, 56P may correspond to the respective concave portions 60R of the protective layer 60. In some embodiments, the convex portion 52P of the first wavelength conversion unit 52 may be disposed on the second light-blocking layer 30. Accordingly, since the wavelength conversion layer 50 may have the convex portion 52P, the light-emitting angle and/or light-emitting efficiency of the subsequently formed light-emitting unit can be improved.

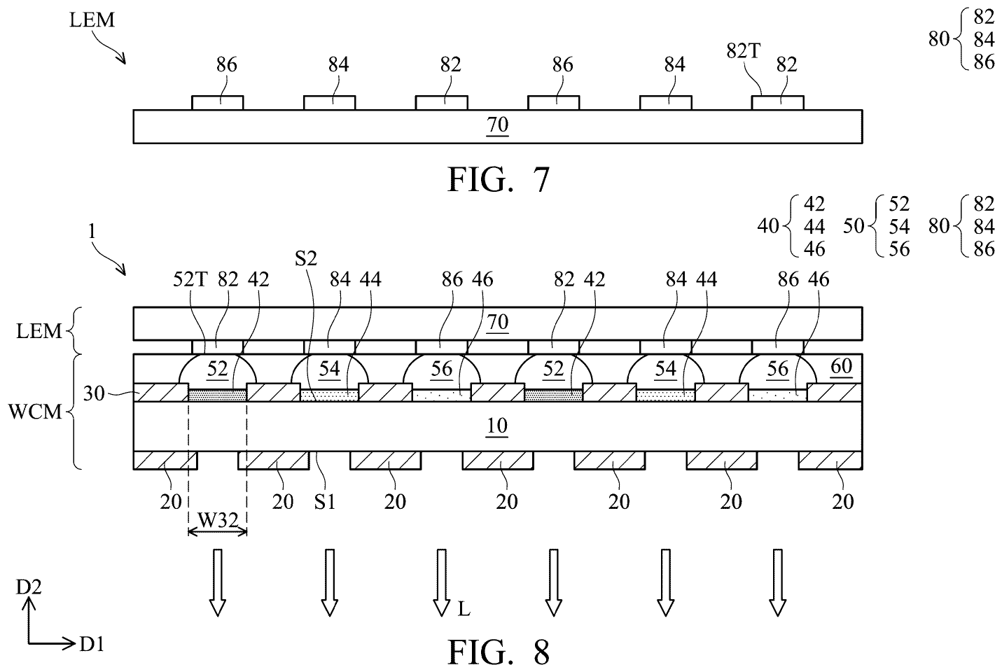

Referring to FIG. 7, it is a schematic cross-sectional view of a wavelength conversion device 1 at a stage in a manufacturing method according to some embodiments of the present disclosure. In some embodiments, a light-emitting module LEM may be formed. In some embodiments, the light-emitting module LEM includes a substrate 70 and a light-emitting element 80. In some embodiments, the substrate 70 may be provided, and the light-emitting element 80 may be formed on the substrate 70 to form the light-emitting module LEM. In some embodiments, the substrate 70 may include a silicon substrate, a glass substrate, a sapphire substrate, a ceramic substrate, a polyimide substrate, a polycarbonate substrate, a polyethylene terephthalate substrate, a polypropylene substrate, other suitable substrates, or a combination thereof, but the present disclosure is not limited thereto.

In some embodiments, the light-emitting element 80 may include a blue micro light-emitting diode (μLED), an ultraviolet (UV) micro light-emitting diode, or a combination thereof. In other embodiments, the micro light-emitting diode may be replaced by a light-emitting diode (LED), a mini light-emitting diode (mini LED), the like, or a combination thereof. In some embodiments, the light-emitting element 80 may include a first light-emitting unit 82 corresponding to the first wavelength conversion unit 52, a second light-emitting unit 84 corresponding to the second wavelength conversion unit 54, and a third light-emitting unit 86 corresponding to the third wavelength conversion unit 56. In some other embodiments, the first light-emitting unit 82, the second light-emitting unit 84, and the third light-emitting unit 86 may all be blue micro light-emitting diodes or ultraviolet micro light-emitting diodes. In some other embodiments, the first light-emitting unit 82 and the second light-emitting unit 84 may be ultraviolet micro light-emitting diodes, and the third light-emitting unit 86 may be the blue micro light-emitting diode.

In some embodiments, the first light-emitting unit 82, the second light-emitting unit 84, and the third light-emitting unit 86 may all be blue micro light-emitting diodes, the first filter 42 may be a red color filter, the second filter 44 may be a green color filter, the third filter 46 may be a blue color filter, and the first wavelength conversion unit 52, the second wavelength conversion unit 54, and the third wavelength conversion unit 56 may respectively include yellow light conversion materials, or may respectively include a combination of green light conversion materials and red light conversion materials. In some embodiments, the first light-emitting unit 82, the second light-emitting unit 84 and the third light-emitting unit 86 may all be blue micro light-emitting diodes, the first filter 42 may be a red filter, the second filter 44 may be a green filter, the third filter 46 may be a blue filter, the first wavelength conversion unit 52 may include a red light conversion material, the second wavelength conversion unit 54 may include a green light conversion material, and the third wavelength conversion unit 56 may include a blue light conversion material or substantially include no light conversion material.

Referring to FIG. 8, it is a schematic cross-sectional view of a wavelength conversion device 1 at a stage in a manufacturing method according to some embodiments of the present disclosure. In some embodiments, the light-emitting module LEM may be provided on the wavelength conversion module WCM to obtain a wavelength conversion device 1. In some embodiments, the light-emitting element 80 of the light-emitting module LEM and the wavelength conversion layer 50 of the wavelength conversion module WCM may be bonded so that the light-emitting element 80 may be interposed between the substrate 70 and the wavelength conversion layer 50. In some embodiments, the second light-blocking layer 30 may be disposed between the substrate 70 and the carrier 10, and the carrier 10 may be disposed between the second light-blocking layer 30 and the first light-blocking layer 20. In some embodiments, the top surface of the wavelength conversion layer 50 (for example, the top surface 52T of the first wavelength conversion unit 52) may be flush with the top surface of the light-emitting element 80 away from the substrate 70 (for example, the top surface 82T of the first light-emitting unit 82).

In some embodiments, as shown in FIG. 8, the light-emitting element 80 can emit a light L, and the light L passes through the wavelength conversion layer 50, the second opening 32 of the second light-blocking layer 30, the carrier 10, and the first opening 22 of the first light-blocking layer 20 in order. In other words, the width of the opening (the second opening 32) of the light-incidence surface of the light L may be greater than the width of the opening (the first opening 22) of the light-emitting surface of the light L. Therefore, when the width W32 of the second opening 32 is greater than the width W22 of the first opening 22, the contrast of the light L can be improved and/or the light L can be prevented from interfering with each other.

Hereinafter, descriptions of the same or similar reference numerals are omitted.

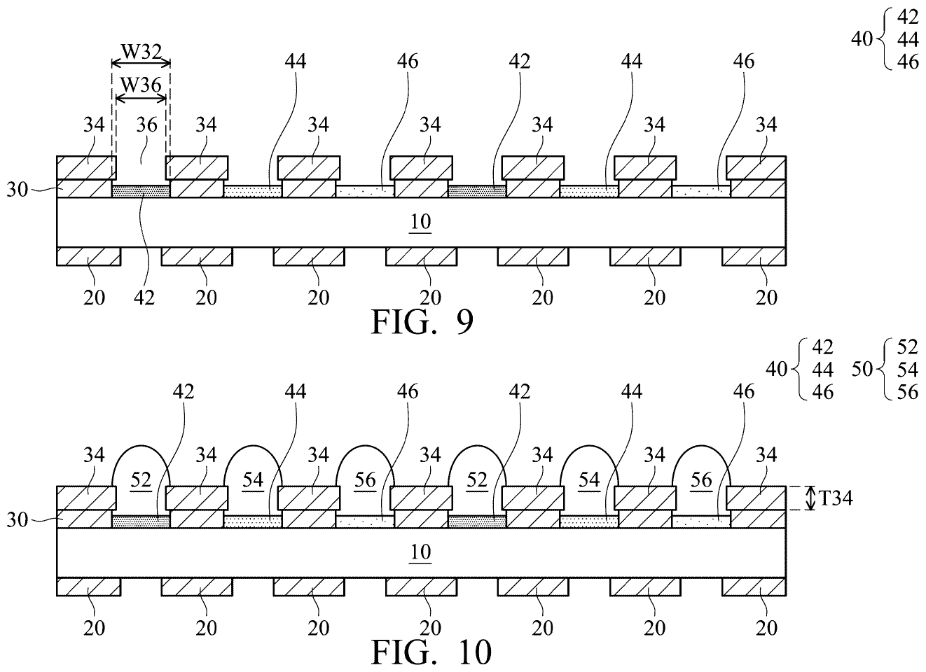

Referring to FIG. 9, it is a schematic cross-sectional view of a wavelength conversion device 2 at a stage in a manufacturing method according to some embodiments of the present disclosure. FIG. 9 is subsequent to FIG. 3. In some embodiments, a third light-blocking layer 34 may be formed on the second light-blocking layer 30, and the third light-blocking layer 34 may have a third opening 36. In some embodiments, the material and the formation method of the third light-blocking layer 34 are the same as or different from the material and the formation method of the second light-blocking layer 30 or the first light-blocking layer 20. In some embodiments, the third light-blocking layer 34 may include a resin, a photoresist material, other suitable light-blocking materials, or a combination thereof, but the present disclosure is not limited thereto. In some embodiments, the third light-blocking layer 34 may be a black glue, a black photoresist material, or a combination thereof. In some embodiments, the first light-blocking layer 20, the second light-blocking layer 30, and the third light-blocking layer 34 may include the black photoresist material, and the protective layer 60 may include the white photoresist material.

In some embodiments, in the first direction D1, the third opening 36 between adjacent third light-blocking layers 34 may have a width W36, and the width W36 of the third opening 36 may be in a range of 10 μm to 600 μm. For example, the width W36 of the third opening 36 may be 10 μm, 50 μm, 100 μm, 200 μm, 300 μm, 400 μm, 500 μm, 600 μm, or any value or any range of values between the aforementioned values, but the present disclosure is not limited thereto. The obtained mixed light can be adjusted by adjusting the width W32 of the second opening 32 and the width W36 of the third opening 36. In some embodiments, the width W36 of the third opening 36 of the third light-blocking layer 34 may be greater than the width W22 of the first opening 22 of the first light-blocking layer 20, and the width W36 of the third opening 36 of the third light-blocking layer 34 may be less than the width W32 of the second opening 32 of the second light-blocking layer 30. In some embodiments, the projection of the third light-blocking layer 34 on the carrier 10 may be located within the projection of the first light-blocking layer 20 on the carrier 10. In some embodiments, the projection of the second light-blocking layer 30 on the carrier 10 may be located within the projection of the third light-blocking layer 34 on the carrier 10. Accordingly, the contrast in the light-emitting side can be increased and/or the light interference can be prevented. In addition, since the width W36 of the third opening 36 may be between the width W22 of the first opening 22 and the width W32 of the second opening 32, the alignment accuracy requirement of the process of forming the third light-blocking layer 34 on the second light-blocking layer 30 may be reduced, thereby reducing the process complexity. Furthermore, because the third light-blocking layer 34 is easier to form on the second light-blocking layer 30, it is easier to adjust the obtained mixed light. In some embodiments, when the width of the opening of the additional light-blocking layer is greater than the width W22 of the first opening 22, the additional light-blocking layer may be further formed on the second light-blocking layer 30 or the third light-blocking layer 34, thereby further increasing the volume of the subsequently formed wavelength conversion layer. In other words, the width of the openings on the light-incident surface (the second opening 32 and the third opening 36) may be greater than the width of the opening on the light-emitting surface (the first opening 22), so as to reduce the process complexity of the openings formed on the light-incident surface, improve the contrast of the light, and/or prevent the light from interfering with each other.

In some embodiments, in the second direction D2, the third light-blocking layer 34 may have a thickness T34, and the thickness T34 of the third light-blocking layer 34 may be in a range of 40 μm to 60 μm. For example, the thickness T34 of the third light-blocking layer 34 may be 40 μm, 42 μm, 44 μm, 46 μm, 48 μm, 50 μm, or any value or any range of values between the aforementioned values, but the present disclosure is not limited thereto. When the thickness T34 of the third light-blocking layer 34 is less than 40 μm, light may interfere with each other or the volume of the wavelength conversion layer 50 may be too small. When the thickness T34 of the third light-blocking layer 34 is greater than 60 μm, the light emitted by the light-emitting element may be over-absorbed, thereby reducing the light-emitting efficiency. Accordingly, since the third light-blocking layer 34 has a thickness T34, the volume of the wavelength conversion layer 50 can be increased, thereby improving the ability of the wavelength conversion layer 50 to convert the wavelength of the light emitted from the light-emitting element 80.

Referring to FIG. 10, it is a schematic cross-sectional view of a wavelength conversion device 2 at a stage in a manufacturing method according to some embodiments of the present disclosure. FIG. 10 may be similar to FIG. 4 described above. In some embodiments, as shown in FIG. 10, the wavelength conversion layer 50 may be formed on the filter layer 40. In some embodiments, the wavelength conversion layer 50 may be formed by micro-jetting the material of the wavelength conversion layer 50 on the filter layer 40 and in the third opening 36 of the third light-blocking layer 34 and the second opening 32 of the second light-blocking layer 30, and then curing the material of the wavelength conversion layer 50. In some embodiments, the wavelength conversion layer 50 may be in direct contact with the third light-blocking layer 34 and the second light-blocking layer 30. In other words, a portion of the wavelength conversion layer 50 may be accommodated in the concave portion formed by the third light-blocking layer 34, the second light-blocking layer 30, and the filter layer 40. Accordingly, because the sidewall height of the concave portion for accommodating the wavelength conversion layer 50 is increased, more material of the wavelength conversion layer 50 can be accommodated, thereby improving the light-emitting efficiency. In some embodiments, as shown in FIG. 10, a portion of the side surface of the wavelength conversion layer 50 may be a curved side surface to increase the side light-emitting efficiency.

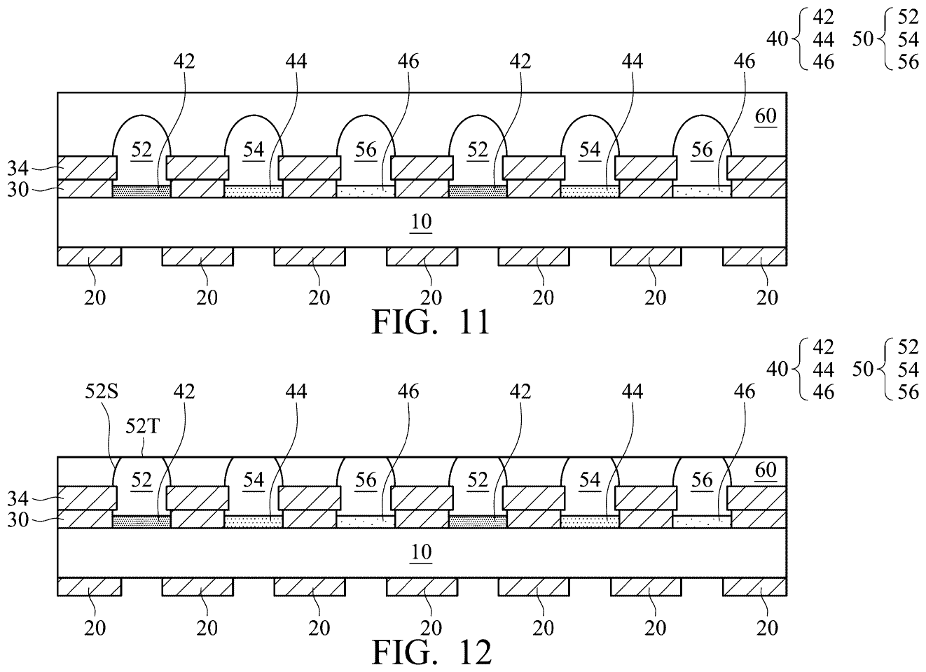

Referring to FIG. 11, it is a schematic cross-sectional view of a wavelength conversion device 2 at a stage in a manufacturing method according to some embodiments of the present disclosure. FIG. 11 may be similar to FIG. 5 described above. In some embodiments, as shown in FIG. 11, the protective layer 60 may be formed on the third light-blocking layer 34 and the wavelength conversion layer 50. In some embodiments, the third light-blocking layer 34 may be in direct contact with the protective layer 60. In some embodiments, the material of the third light-blocking layer 34 may be different from the material of the protective layer 60.

Referring to FIG. 12, it is a schematic cross-sectional view of a wavelength conversion device 2 at a stage in a manufacturing method according to some embodiments of the present disclosure. FIG. 12 may be similar to the aforementioned FIG. 6. In some embodiments, as shown in FIG. 12, the planarization process may be performed to remove a portion of the protective layer 60 and a portion of the wavelength conversion layer 50. Therefore, the top surface of the protective layer 60 may be substantially coplanar with the top surface of the wavelength conversion layer 50.

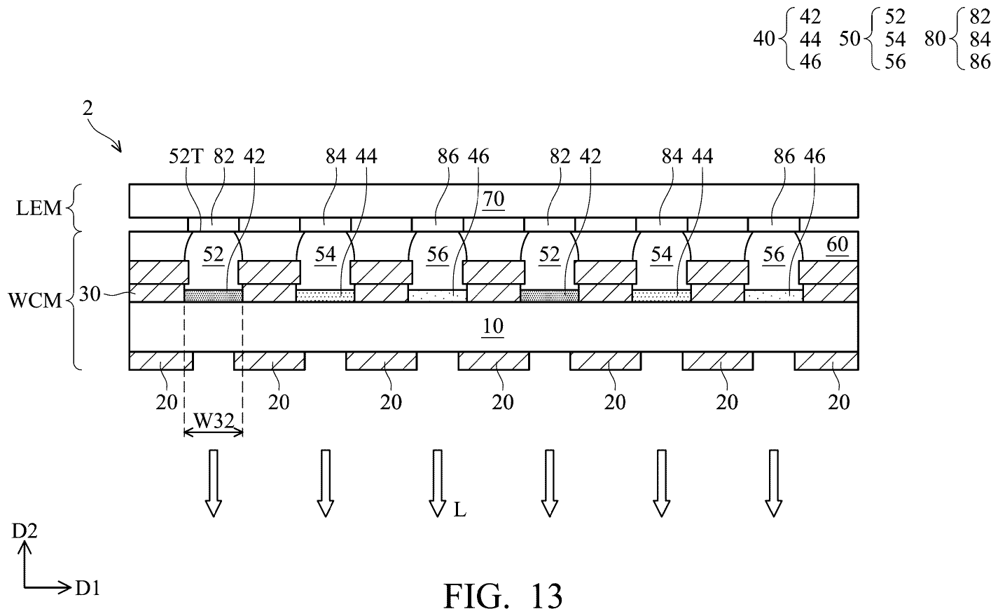

Referring to FIG. 13, it is a schematic cross-sectional view of a wavelength conversion device 2 at a stage in a manufacturing method according to some embodiments of the present disclosure. FIG. 13 may be similar to the aforementioned FIG. 8. In some embodiments, as shown in FIG. 13, the light-emitting element 80 can emit the light L, and the light L passes through the wavelength conversion layer 50, the third opening 36 of the third light-blocking layer 34, the second opening 32 of the second light-blocking layer 30, the carrier 10, and the first opening 22 of the first light-blocking layer 20 in order. In other words, the width of the openings (the third opening 36 and the second opening 32) of the light-incident surface of the light L may be greater than the width of the opening (the first opening 22) of the light-emitting surface of the light L. Therefore, when the width W36 of the third opening 36 and the width W32 of the second opening 32 are greater than the width W22 of the first opening 22, the contrast of the light L emitted by the light-emitting element 80 can be improved and/or the light can be prevented from interfering with each other.

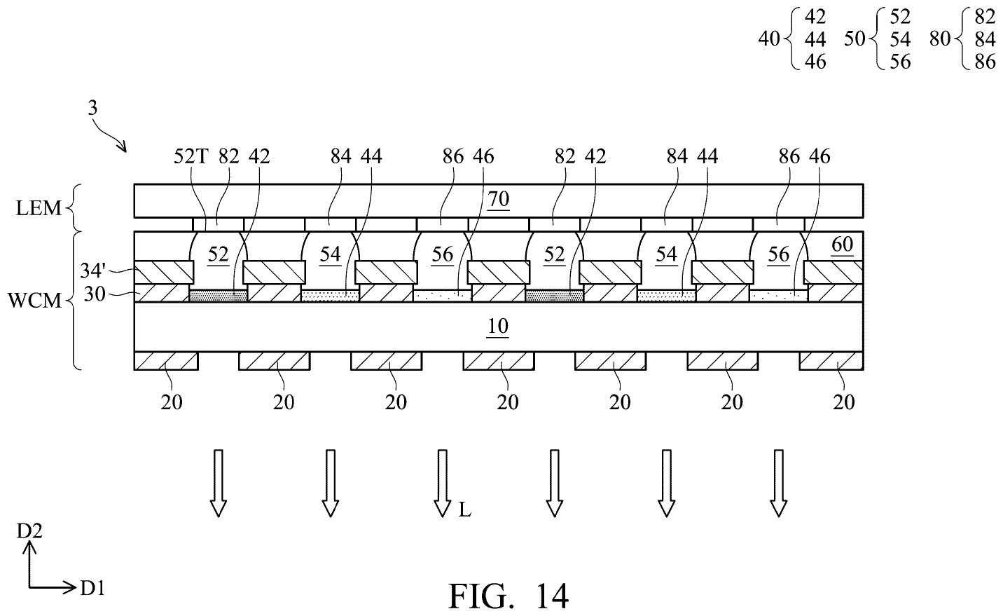

Referring to FIG. 14, it is a schematic cross-sectional view showing a wavelength conversion device 3 according to some embodiments of the present disclosure. The wavelength conversion device 3 shown in FIG. 14 may be similar to the wavelength conversion device 2 shown in FIG. 13. In some embodiments, the wavelength conversion device 3 may include a third light-blocking layer 34′. In some embodiments, the wavelength conversion layer 50 may be in direct contact with the third light-blocking layer 34′ and the second light-blocking layer 30. In some embodiments, the third light-blocking layer 34′ may include a reflective material. In some embodiments, the reflective material may include a white reflective material (such as, a white paint or other white material), a white photoresist material, the like, or a combination thereof, but the present disclosure is not limited thereto. In some embodiments, the material of the third light-blocking layer 34′ may be the same as the material of the protective layer 60. In some embodiments, the first light-blocking layer 20 and the second light-blocking layer 30 may include the black photoresist material, and the third light-blocking layer 34′ and the protective layer 60 may include the white photoresist material. Accordingly, the third light-blocking layer 34′ can improve the contrast, reduce light interference, improve the light-emitting efficiency, and/or improve the light-emitting angle of the wavelength conversion device 3.

In some embodiments, any one of the aforementioned wavelength conversion devices 1-3 or any combination thereof can be used as a direct-lit backlight device.

In summary, the wavelength conversion device disclosed herein includes a wavelength conversion module, and the wavelength conversion module includes light-blocking layers with different opening widths (for example, a first light-blocking layer, a second light-blocking layer, and a third light-blocking layer), thereby increasing the contrast of the wavelength conversion device, reducing light interference, improving light-emitting efficiency, and/or improving light-emitting angle. For example, because the width of the second opening of the second light-blocking layer is greater than the width of the first opening of the first light-blocking layer, the contrast can be improved and the light interference can be reduced. For example, since the third light-blocking layer is disposed on the second light-blocking layer, the total volume of the wavelength conversion layer can be increased, thereby improving the light-emitting efficiency. For example, because the wavelength conversion layer has a curved side surface, the light-emitting efficiency and the light-emitting angle can be improved.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A wavelength conversion device, comprising:
a wavelength conversion module (WCM), comprising:
a carrier having a first surface and a second surface opposite the first surface;
a first light-blocking layer disposed on the first surface and having a first opening;
a second light-blocking layer disposed on the second surface and having a second opening;
a filter layer disposed on the second surface and disposed in the second opening;
a wavelength conversion layer disposed on the filter layer; and
a protective layer disposed on the second light-blocking layer; and
a light-emitting module (LEM) disposed on the wavelength conversion module,
wherein a width of the second opening of the second light-blocking layer is greater than a width of the first opening of the first light-blocking layer.

2. The wavelength conversion device as claimed in claim 1, wherein a portion of a side surface of the wavelength conversion layer is a curved side surface.

3. The wavelength conversion device as claimed in claim 1, wherein a side surface of the wavelength conversion layer is in contact with the protective layer.

4. The wavelength conversion device as claimed in claim 1, wherein the wavelength conversion layer has a convex portion, and the protective layer has a concave portion corresponding to the convex portion.

5. The wavelength conversion device as claimed in claim 1, wherein the protective layer comprises a reflective material.

6. The wavelength conversion device as claimed in claim 1, wherein the wavelength conversion module further comprises:
a third light-blocking layer disposed on the second light-blocking layer.

7. The wavelength conversion device as claimed in claim 6, wherein the third light-blocking layer comprises a black photoresist material or a white photoresist material.

8. The wavelength conversion device as claimed in claim 6, wherein the wavelength conversion layer is in contact with the third light-blocking layer and the second light-blocking layer.

9. The wavelength conversion device as claimed in claim 6, wherein the third light-blocking layer has a third opening, and a width of the third opening of the third light-blocking layer is smaller than the width of the second opening of the second light-blocking layer.

10. The wavelength conversion device as claimed in claim 1, wherein the light-emitting module further comprises:
a substrate; and
a light-emitting element disposed on the substrate, wherein the wavelength conversion layer is disposed between the light-emitting element and the filter layer.

11. The wavelength conversion device as claimed in claim 10, wherein the second light-blocking layer is disposed between the substrate and the carrier, and the carrier is disposed between the second light-blocking layer and the first light-blocking layer.

12. The wavelength conversion device as claimed in claim 10, wherein a top surface of the wavelength conversion layer is flush with a surface of the light-emitting element.

13. The wavelength conversion device as claimed in claim 10, wherein the light-emitting element comprises a blue micro light-emitting diode, an ultraviolet micro light-emitting diode, or a combination thereof.

14. The wavelength conversion device as claimed in claim 1, wherein a projection of the second light-blocking layer on the carrier is located within a projection of the first light-blocking layer on the carrier.

15. A method for manufacturing a wavelength conversion device, comprising:
providing a carrier having a first surface and a second surface opposite the first surface;
forming a first light-blocking layer on the first surface, wherein the first light-blocking layer has a first opening;
forming a second light-blocking layer on the second surface, wherein the second light-blocking layer has a second opening;
forming a filter layer on the second surface and in the second opening;
forming a wavelength conversion layer on the filter layer;
forming a protective layer on the second light-blocking layer; and
providing a light-emitting module (LEM) on the wavelength conversion layer,
wherein, a width of the second opening of the second light-blocking layer is greater than a width of the first opening of the first light-blocking layer.

16. The manufacturing method as claimed in claim 15, wherein the step of forming the wavelength conversion layer on the filter layer further comprises:
micro-jetting a material of the wavelength conversion layer on the filter layer; and
curing the material of the wavelength conversion layer to form the wavelength conversion layer.

17. The manufacturing method as claimed in claim 15, further comprises:
forming a third light-blocking layer on the second light-blocking layer, wherein the third light-blocking layer has a third opening.

18. The manufacturing method as claimed in claim 17, wherein the step of forming the wavelength conversion layer on the filter layer further comprises:
micro-jetting a material of the wavelength conversion layer on the filter layer and in the third opening of the third light-blocking layer; and
curing the material of the wavelength conversion layer to form the wavelength conversion layer.

19. The manufacturing method as claimed in claim 15, wherein providing the light-emitting module on the wavelength conversion layer further comprises:
providing a substrate;
forming a light-emitting element on the substrate to form the light-emitting module; and
bonding the light-emitting element of the light-emitting module and the wavelength conversion layer, so that the light-emitting element is located between the substrate and the wavelength conversion layer.

20. The manufacturing method as claimed in claim 15, wherein the step of forming the filter layer on the second surface and in the second opening further comprises:
coating a material of the filter layer on the second surface and in the second opening; and
curing the material of the filter layer to form the filter layer.
